(19) United States
(12) Patent Application Publication
(10) Pub. No.: US 2012/0307874 A1
(43) Pub. Date: Dec. 6, 2012

(54) CDR CIRCUIT, RECEIVER, AND TRANSMITTING-RECEIVING SYSTEM

(75) Inventors: Daisuke HAMANO, Hachioji (JP); Tatsunari USUGI, Inagi (JP)

(73) Assignee: HITACHI, LTD.

(21) Appl. No.: 13/485,086

(22) Filed: May 31, 2012

(30) Foreign Application Priority Data
Jun. 3, 2011 (JP) 2011-124790

(51) Int. Cl. H03L 7/00; H04B 1/38; H04B 1/06

(52) U.S. Cl. 375/219; 375/316; 327/161

(57) ABSTRACT

A CDR circuit, a receiver, and a transmitting-receiving system weight the output of the nonlinear phase detector that receives received data and the recovery clock on the basis of whether a clock out-of-phase with the recovery clock lags or leads in phase with respect to the received data, and adjust the phase of the recovery clock on the basis of the weighted output.

### CLAIM OF PRIORITY

The present application claims priority from Japanese patent application JP 2011-124790 filed on Jun. 3, 2011, the content of which is hereby incorporated by reference into this application.

### FIELD OF THE INVENTION

The present invention relates to a transmitting-receiving system, and more specifically to a useful technology for use in a clock and data recovery (CDR) circuit and a receiver for recovering a clock from received data.

### BACKGROUND OF THE INVENTION

A receiver may include a clock and data recovery (CDR) circuit for extracting a clock from received data to recover data from the received data. A CDR circuit includes a phase detector for determining the phase difference between the received data and the recovery clock. Such phase detectors fall into two general, classes: linear phase detectors and nonlinear phase detectors (Japanese Unexamined Patent Application Publication No. 2002-84187). Linear phase detectors determine the phase difference between the received data and the recovery clock accurately. In contrast, nonlinear phase detectors generate a phase control signal for the recovery clock only on the basis of whether the edge of the received data exists in the vicinity of the edge of the recovery clock, thus resulting in their circuitry configuration being simplified. This enables the circuitry size and power consumption of nonlinear phase detectors to be reduced when compared with linear phase detectors. Japanese Unexamined Patent Application Publication No. 2006-339858 discloses a technology for quickly determining a phase for sampling by selecting one of a plurality of clocks for use in sampling.

### SUMMARY OF THE INVENTION

While incorporating a linear phase detector into a CDR circuit may complicate its circuitry configuration and therefore increase the circuitry size and power consumption thereof, incorporating a nonlinear phase detector into a CDR circuit may reduce the tracking accuracy of the recovery clock to the received data because nonlinear phase detectors only detect whether the edge of the received data exists in the vicinity of the edge of the recovery clock.

An object of the present invention is to improve the phase tracking accuracy of the recovery clock in a CDR circuit, a receiver, and a transmitting-receiving system including a nonlinear phase detector.

To briefly summarize typical aspects of the present invention disclosed herein, a CDR circuit, a receiver, and a transmitting-receiving system according the invention weight the output of a nonlinear phase detector that receives received data and a recovery clock, on the basis of whether a clock out-of-phase with the recovery clock lags or leads in phase with respect to the received data, and adjust the phase of the recovery clock on the basis of the weighted output.

With the function summarized above, it is possible to improve the phase tracking accuracy of the recovery clock to the received data in a CDR circuit, a receiver, and a transmitting-receiving system including a nonlinear phase detector.

### BRIEF DESCRIPTION OF THE DRAWINGS

FIG. 1 is a block diagram showing a transmitting-receiving system according to an embodiment of the present invention;

FIG. 2 is a block diagram showing an exemplary configuration of a phase detector included in a CDR circuit according to the embodiment of the invention;

FIG. 3 is a diagram showing exemplary operational waveforms of the phase detector included in the CDR circuit according to the embodiment of the invention; and

FIG. 4 is a diagram showing the relationship between the phase difference and the weighting factor in the embodiment according to the invention.

### DETAILED DESCRIPTION OF THE PREFERRED EMBODIMENT

The present invention will now be described in detail using an embodiment thereof.

### First Embodiment

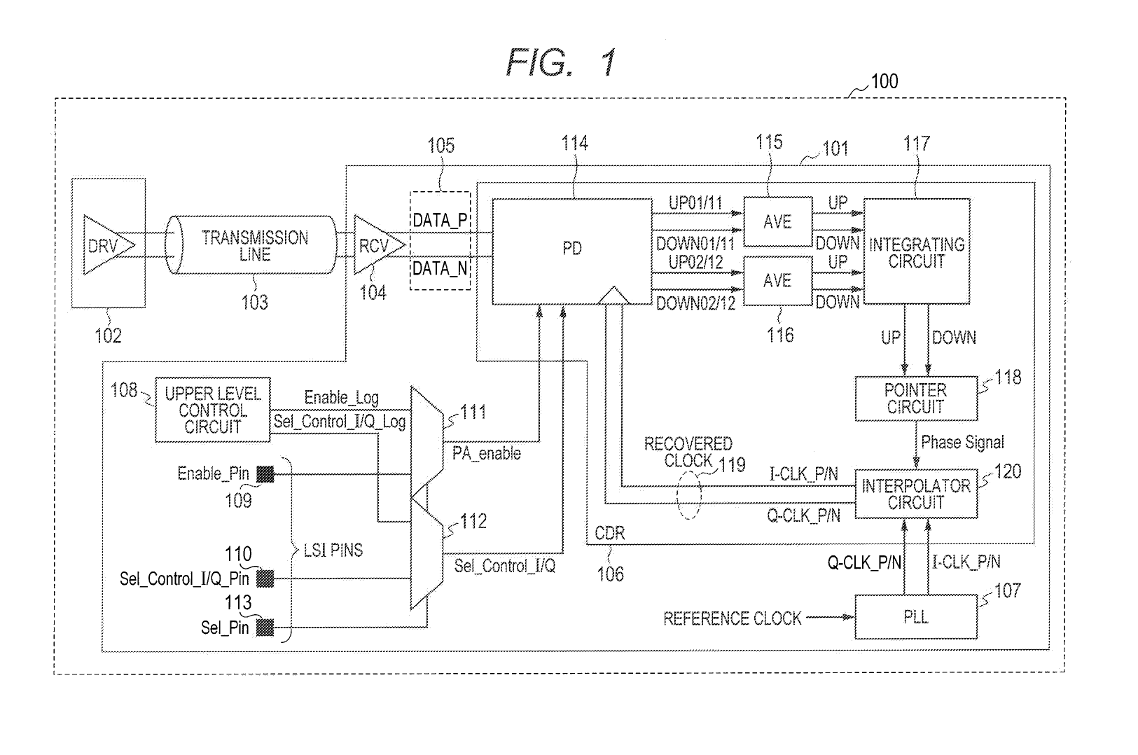

FIG. 1 shows a transmitting-receiving system 100 according to an embodiment of the invention. The transmitting-receiving system 100 includes a receiver 101, a transmitter 102, and a transmission line 103. The receiver 101 includes a receiver circuit 104 for receiving data transmitted from the transmitter 102 via the transmission line 103, a CDR circuit 106 for recovering data from the received data 105 output from the receiver circuit 104, a PLL (Phase Locked Loop) circuit 107 for supplying a clock to the CDR circuit 106, an upper level control circuit 108, selector circuits 111 and 112, a control terminal (Sel_Pin) 113 for receiving a control signal for the selector circuits 111 and 112. The selector circuits 111 and 112 can select either control signals sent from the upper level control circuit 108 to the CDR circuit 106 or control signals sent from a control terminal (Enable_Pin) 109 and a control terminal (Sel_control_I/Q_Pin) 110 to the CDR circuit 106.

The CDR circuit 106 includes a phase detector 114 for weighting phase lag or lead information of a recovery clock 119 relative to the received data 105 on the basis of whether a clock out-of-phase with the recovery clock lags or leads in phase with respect to the received data 105 and outputting a phase comparison result, an averaging circuit 115 for averaging the output of the phase detector 114 when the phase difference between the received data 105 and the recovery clock 119 is small, an averaging circuit 116 for averaging the output of the phase detector 114 when the phase difference between the received data 105 and the recovery clock 119 is large, an integrating circuit 117 for integrating the output signals of the averaging circuits 115 and 116, a pointer circuit 118 for controlling the phase of the recovery clock 119 on the basis of the output of the integrating circuit 117, and an interpolator circuit 120 for generating the recovery clock 119 having a phase specified by the pointer circuit 118. The recovery clock 119 includes an I-clock component and a Q-clock component that are 90 degrees out-of-phase with each other. The CDR circuit 106 recovers data from the received data 105 by latching the received data using the I-clock in a latch circuit that is not shown.

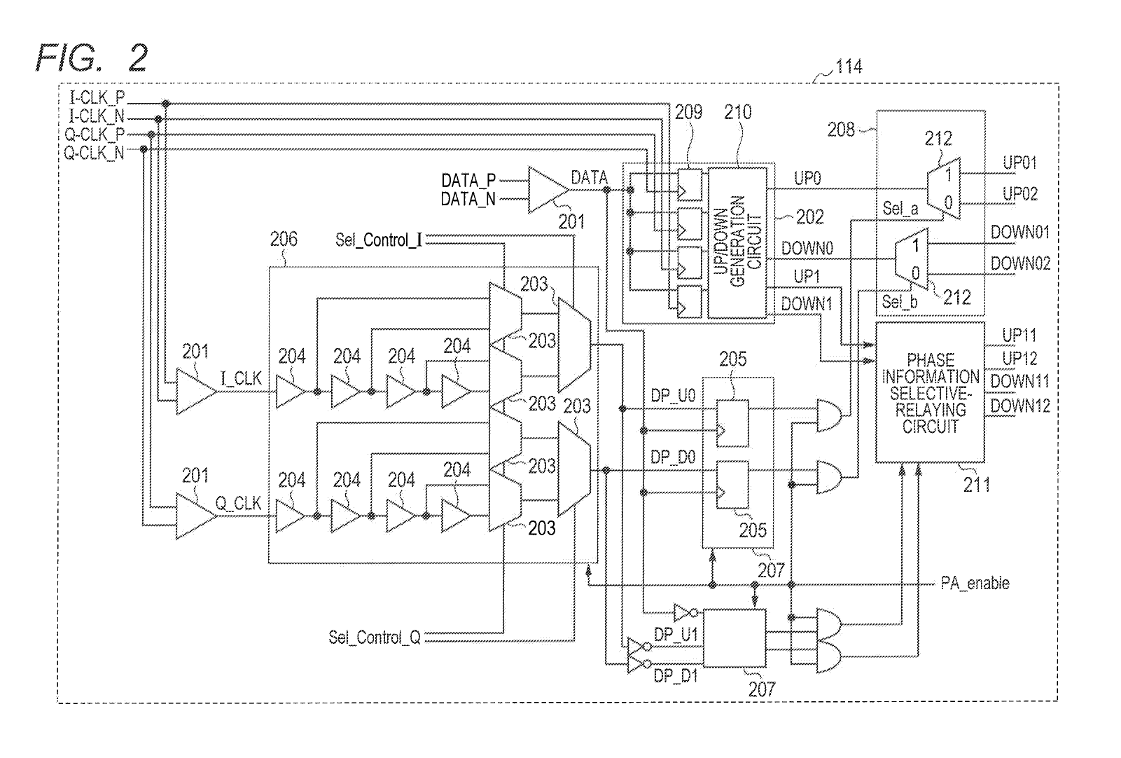

FIG. 2 shows the phase detector 114 according to the embodiment. The phase detector 114 includes differential single phase converters 201, a nonlinear phase detector 202, a selective-relaying reference signal generation circuit 206, selective-relaying signal generation circuits 207, and phase information selective-relaying circuits 208 and 211. The phase detector 114 has a function for selectively relaying phase control information (UP0, UP1, DOWN0, DOWN1) output from the nonlinear phase detector 202 to a plurality of output terminals (DOWN01, DOWN02, DOWN11, DOWN12, UP01, UP02, UP11, UP12) on the basis of the phase difference between the received data 105 and the recovery clock 119.

The differential single phase converters 201 convert the differential signal constituted by the negative signal (DATA_N) and the positive signal (DATA_P) of the received data 105 into single phase CMOS level received data (DATA), convert the differential signal constituted by the negative signal (I_CLK_N) and the positive signal (I-CLK_P) of the I-clock component of the recovery clock 119 into a single phase CMOS level P-clock component (I_CLK), and convert the differential signal constituted by the negative signal (Q-CLK_N) and the positive signal (Q-CLK_P) of the Q-clock component of the recovery clock 119 into a single phase CMOS level Q-clock component (Q_CLK), respectively.

The nonlinear phase detector 202 latches the received data (DATA) using four flip-flop circuits 209 and generates phase control signals (UP0, UP1, DOWN0, DOWN1) for controlling the phase of the recovery clock using an UP/DOWN generation circuit 210. Of these phase control signals, UP0 and UP1 are generated when the recovery clock 119 lags in phase with respect to the received data (DATA) while DOWN0 and DOWN1 are generated when the recovery clock 119 leads in phase with respect to the received data (DATA).

The phase detector in the present embodiment operates at a half rate so that the phase lag or lead is determined at both the rising and falling edges of the recovery clock. As a result, the phase lead signals UP0 and UP1 and the phase lag signals DOWN0 and DOWN1 are generated at both the rising and falling edges. When the phase difference between the received data (DATA) and the recovery clock 119 falls below a selective-relaying reference described below, phase control signals UP01, UP11, DOWN01 and DOWN11 are output from the phase detector 114. In contrast, when the phase difference between the received data (DATA) and the recovery clock 119 exceeds the selective-relaying reference described below, phase control signals UP02, UP12, DOWN02, and DOWN12 are output.

The selective-relaying reference signal generation circuit 206 generates reference signals for determining the phase difference between the received data (DATA) and the recovery clock 119. As shown in FIG. 2, the selective-relaying reference signal generation circuit 206 includes delay buffer circuits 204 and selectors 203, and generates the selective-relaying reference signals by shifting the phase of I_CLK or Q_CLK. That is, the delay buffer circuits 204 and the selectors 203 constitute delay elements. The generated selective-relaying reference signals include DP_U0 and DP_D0, and also includes DP_U1 and DP_D1 generated via inverters.

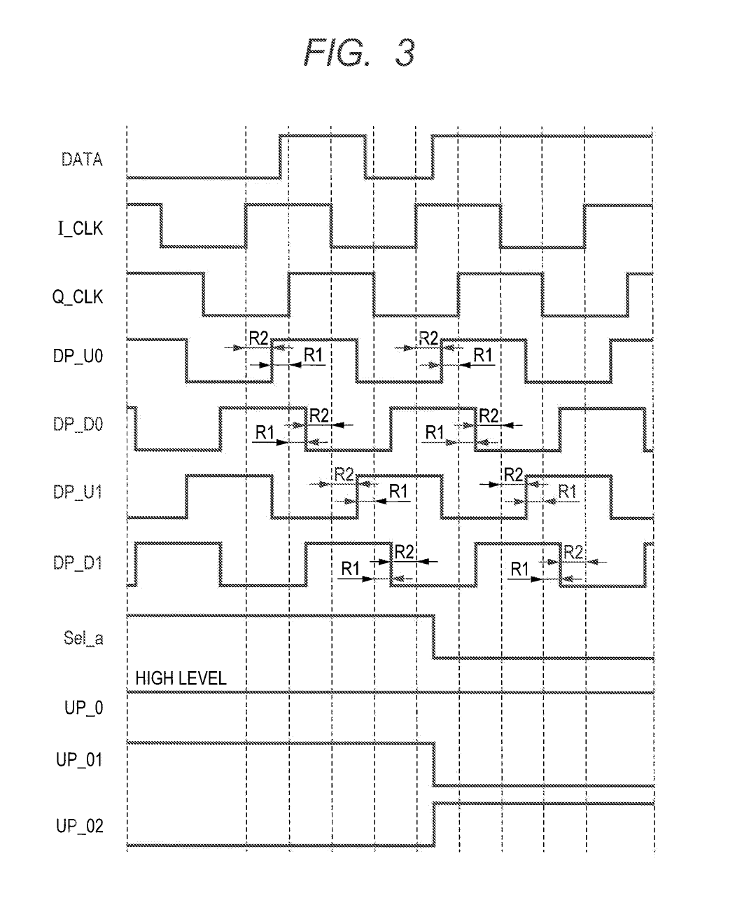

FIG. 3 is a diagram showing exemplary operational waveforms of the phase detector 114. As shown in FIG. 3, the selective-relaying reference signals (DP_U0, DP_D0, DP_U1, DP_D1) are generated so that the clock edges of the selective-relaying reference signals (DP_U0, DP_D0, DP_U1, DP_D1) exist in the vicinity of the rising and falling edges of Q_CLK that tracks the edges of the received data (DATA). As shown in FIG. 3, regions R1 and R2 are defined on the basis of the clock pulses of the selective-relaying reference signals (DP_U0, DP_D0, DP_U1, DP_D1). While the region R1 corresponds to the case in which the voltages of the selective-relaying reference signals are at the high level, the region R2 corresponds to the case in which the voltages of the selective-relaying reference signals are at the low level. The phase difference with respect to the edge of Q_CLK is small in the region R1 and large in the region R2. Because the CDR circuit 106 in the present embodiment operates at a half rate and the received data is latched using I_CLK, the regions R1 and P2 are defined in the vicinity of both the rising and falling edges of Q_CLK. The time widths of the regions R1 and R2 can be changed by controlling the selectors 203 using the control signals Sel_Control_I and Sel_Control_Q input from outside the selective-relaying reference signal generation circuit 206 so as to change the number of stages of the delay buffer circuits 204.

The selective-relaying signal generation circuits 207 detect whether the edge of the received data (DATA) exists in the region R1 or in the region R2 by obtaining the selective-relaying reference signals (DP_U0, DP_D0, DP_U1, DP_D1) using flip-flop circuits 205 driven by the received data (DATA). When the result obtained by the flip-flop circuits 205 is at the high level, the edge of the received data is detected as existing in the region R1, and when the result obtained by the flip-flop circuits 205 is at the low level, the edge of the received data is detected as existing in the region R2, for example.

The outputs of the selective-relaying signal generation circuits 207 are input to the phase information selective-relaying circuits 208 and 211. By controlling selector circuits 212 included in the phase information selective-relaying circuit 208 using the output of the selective-relaying signal generation circuit 207, the phase lag signal (DOWN0) and the phase lead signal (UP0) generated by the nonlinear phase detector 202 are selectively relayed to the averaging circuit 115 as DOWN01 and UP01 when the phase difference between the received data 105 and the recovery clock 119 falls below a selective-relaying reference, and are selectively relayed to the averaging circuit 116 as DOWN02 and UP02 when the phase difference between the received data 105 and the recovery clock 119 exceeds the selective-relaying reference. Similar to the phase information selective-relaying circuit 208, the phase information selective-relaying circuit 211 also selectively relays the phase lag signal (DOWN1) and the phase lead signal (UP1) to the averaging circuit 115 as DOWN11 and UP11 when the phase difference between the received data 105 and the recovery clock 119 falls below the selective-relaying reference and to the averaging circuit 116 as DOWN12 and UP12 when the phase difference between the received data 105 and the recovery clock 119 exceeds the selective-relaying reference.

For example, when an edge of the received data (DATA) exists in the region R1 at a certain point of time, the phase difference between the received data (DATA) and the recovery clock 119 is determined small, and the phase control information (the phase lag signal or the phase lead signal) calculated on the basis of the data edge is processed in the averaging circuit 115 for the region R1. In contrast, when an edge of the received data (DATA) exists in the region R2 at a certain point of time, the phase difference between the received data (DATA) and the recovery clock 119 is determined large, and the phase control information (the phase lag signal or the phase lead signal) calculated on the basis of the data edge is processed in the averaging circuit 116 for the region R2. In this manner, the processing for averaging the phase information is performed by either the averaging circuit 115 or the averaging circuit 116 on the basis of the magnitude of the phase difference between the received data (DATA) and the recovery clock 119.

According to the phase relationship between the first rising edge of the received data (DATA) and the recovery clock (Q_CLK) shown in FIG. 3, the edge of the received data (DATA) exists in the region R1. As a result, when the selective-relaying reference signals (DP_U0, DP_D0, DP_U1, DP_D1) generated by the selective-relaying reference signal generation circuit 206 are latched by the received data (DATA) that has passed through the differential single phase converter 201, the selective-relaying signal generation circuit 207 outputs a signal Sel_a at the high level. On the basis of this high level output signal, the phase information selective-relaying circuit 208 relays the phase control signals output from the nonlinear phase detector 202 to the averaging circuit 115 that performs the averaging processing when the phase difference is small.

According to the phase relationship between the second rising edge of the received data (DATA) and the recovery clock (Q_CLK) shown in FIG. 3, because the edge of the received data exits in the region R2, the signal Sel_a is output at the low level. On the basis of this low level output signal, the phase information selective-relaying circuit 208 relays the phase control signals output from the nonlinear phase detector 202 to the averaging circuit 116 that performs the averaging processing when the phase difference is large. In this manner, the phase detector 114 selectively relays the phase control signals output from the nonlinear phase detector 202 either to the following averaging circuit 115 or to the following averaging circuit 116 on the basis of whether the edge of the received data exists in the region R1 or in the region R2.

While nonlinear phase detectors typically determine the phase difference between the received data and the recovery clock only on the basis of whether the edge of the received data exists in the vicinity of the edge of the recovery clock, linear phase detectors perform phase tracking of the recovery clock to the received data on the basis of accurate phase difference information. As a result, a CDR circuit including a nonlinear phase detector is inferior to a CDR circuit including a linear phase detector in the phase tracking accuracy and phase tracking speed. In the present embodiment, the signals output from the phase detector 114 are selectively relayed either to the following averaging circuit 115 or to the following averaging circuit 116 on the basis of the selective-relaying reference signals generated by the selective-relaying reference signal generation circuit 206. As a result, information based on the magnitude of the phase difference can be added to the phase control information generated by the non-liner phase detector 202. This enables more accurate phase information processing to be performed because the information about the magnitude of the phase difference can be added to the phase control information generated by the nonlinear phase detector 202, which typically reflects only the presence or absence of the edge. Since the phase detector 114 can perform a liner phase detector-like operation using a nonlinear phase detector, the output can be weighted in the integrating circuit 117 as described below, thereby enabling the phase tracking accuracy and phase tracking speed of the CDR circuit 106 to be improved when compared with an existing CDR circuit including a nonlinear phase detector. Furthermore, because the phase difference is determined discretely, an increase in power consumption can be suppressed when compared with the case in which a linear phase detector is used. As a result, not only the phase tracking accuracy and phase tracking speed can be improved but also an increase in power consumption can be suppressed in the receiver 101 and the transmitting-receiving system 100 including the CDR circuit 106. Instead of selectively relaying the output using a plurality of averaging circuits as in the present embodiment, it is also possible to obtain the same advantage as the present embodiment by using only one averaging circuit and inputting a signal weighted on the basis of the magnitude of the phase difference to the averaging circuit.

The functions of the selective-relaying reference signal generation circuit 206 and the selective-relaying signal generation circuits 207 can be turned on and off from outside the CDR circuit 106 using a phase selective-relaying enable signal PA_enable. For example, these functions may be turned on when improving the phase tracking accuracy is more important than suppressing the power consumption. Conversely, these functions may be turned off when suppressing the power consumption is more important than improving the phase tracking accuracy. By controlling the enable signal PA_enable, the CDR circuit can be flexibly adjusted so as to meet the requirements therefor.

The time widths of the regions R1 and R2 can be changed by controlling the selector circuits 203 included in the selective-relaying reference signal generation circuit 206 from outside the CDR circuit 106. Furthermore, although in the present embodiment, the phase difference is determined using two regions, i.e., the regions R1 and R2, the number of regions can be increased by increasing the number of delay elements. Increasing the number of regions allows more linear phase detector-like processing to be performed, thereby enabling the phase tracking accuracy and phase tracking speed to be improved further. As the nonlinear phase detector 202 and the averaging circuits 115 and 116 are configured in a conventional manner, detailed description will be omitted.

After processed in the averaging circuit 115 when the phase difference is determined to fall below the reference, or after processed in the averaging circuit 116 when the phase difference is determined to exceed the reference, the phase control information is integrated in the following integrating circuit 117. This integrating circuit 117 generates the final phase control information for controlling the pointer circuit 118.

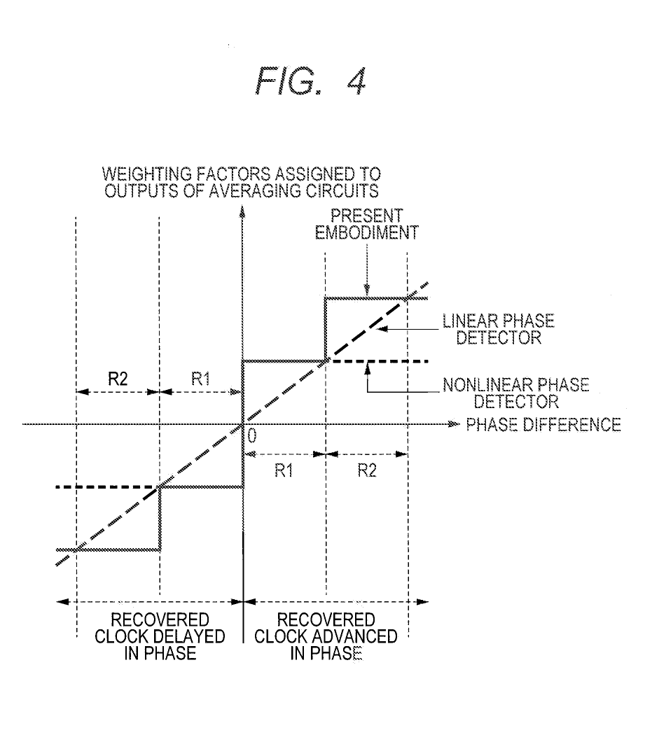

The integrating circuit 117 weights the signals output from the averaging circuits 115 and 116 each associated with one of the regions, as shown in FIG. 4, and performs integrating processing for each of the phase lead and lag signals. The horizontal axis of the graph shown in FIG. 4 shows the phase difference between the received data (DATA) and the recovery clock (Q_CLK) while the vertical axis shows the weighting factor applied to the output signals of the averaging circuits 115 and 116. In the present embodiment, the output signals of the averaging circuit 116 are weighted greater than the output signals of the averaging circuit 115 by a factor of two, as shown in FIG. 4. In this manner, a different weighting factor is assigned to each of the averaging circuits to which the phase detector 114 outputs. When the number of regions is increased, the weighting factor is increased with increasing phase difference. The integrating circuit 117 compares the integrating processing results and selects and outputs a signal having a larger integrated amount from among the phase lead and lag signals. Furthermore, in this comparison of the results, it is also possible to set a plurality of threshold values and specify a different phase shift amount of the recovery clock for each threshold value so that the phase of the recovery clock is shifted by an amount corresponding to each threshold value when the threshold value is exceeded.

About the phase detector 114, the phase information selective-relaying function can be turned on and off and the time widths of the regions R1 and R2 can be changed from outside the CDR circuit 106. This external control can be achieved either through the LSI pins or through the upper level control circuit 108, i.e., the upper level logic circuit for the CDR circuit 106. One of these two control paths can be selected by the selector circuit 111. By using the upper level control circuit 108, the phase selective-relaying function can be kept either turned on or off throughout the operation of the CDR circuit 106, the phase selective-relaying function can be turned on or off upon the elapse of a predetermined time period, e.g., after data reception has been started, and the phase selective-relaying function can be turned on or off using as a parameter the operating rate, the frequency characteristics of the transmission line, or the like, for example.

The present invention is not limited to the above described embodiment, and modifications may be made without departing from the scope of the invention.

What is claimed is:

1. A CDR circuit, comprising:
a nonlinear phase detector that receives received data and a recovery clock having a phase and outputs an output;
a delay element that receives the recovery clock and outputs an output;
a flip-flop circuit that latches the output of the delay element using the received data and outputs an output; and
a selector that selects one of a plurality of following circuits to relay the output of the nonlinear phase detector based on the output of the flip-flop circuit,
wherein the phase of the recovery clock is controlled using a different weighting factor for each of the following circuits.

2. The CDR circuit according to claim 1, wherein the weighting factor is increased with increasing phase difference between the received data and the recovery clock.

3. The CDR circuit according to claim 1, further comprising:
an upper level control circuit,
wherein the controlling is turned on and off using a control signal from the upper level control circuit.

4. The CDR circuit according to claim 1, further comprising:
a control terminal,
wherein the controlling is turned on and off based on an input from the control terminal.

5. A receiver comprising the CDR device according to claim 1.

6. A transmitting-receiving system comprising the receiver according to claim 5.

7. A CDR circuit comprising:
a nonlinear phase detector that receives received data and a recovery clock having a phase and outputs an output,
wherein the output of the nonlinear phase detector is weighted based on whether a clock out-of-phase with the recovery clock lags or leads in phase with respect to the received data, and
wherein the phase of the recovery clock is adjusted based on the weighted output.

8. The CDR circuit according to claim 7, further comprising:
an upper level control circuit,
wherein the weighting is turned on and off using a control signal from the upper level control circuit.

9. The CDR circuit according to claim 7, further comprising:
a control terminal,
wherein the weighting is turned on and off based on an input from the control terminal.

10. A receiver comprising the CDR circuit according to claim 7.

11. A transmitting-receiving system comprising the receiver according to claim 10.
